(19) United States
(12) Patent Application Publication
(10) Pub. No.: US 2007/0108496 A1
(43) Pub. Date: May 17, 2007

(54) NONVOLATILE SEMICONDUCTOR STORAGE DEVICE AND METHOD OF MANUFACTURE THEREOF

(76) Inventor: Kazumi INO, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/557,266

(22) Filed: Nov. 7, 2006

(30) Foreign Application Priority Data
Nov. 15, 2005 (JP) 2005-330417

(51) Int. Cl. H01L 21/336

(52) U.S. Cl. 257/314; 257/315; 438/257

(57) ABSTRACT

In a nonvolatile semiconductor storage device, memory cell units of two-transistor structure are arranged in rows and columns and adjacent rows of memory cell units are isolated by a trench-type device isolation region. The spacing between the control gate electrode of a cell transistor and the gate electrode of a select gate transistor which adjoin in the column direction in each memory cell unit is set shorter than the spacing between the control gate electrodes of cell transistors which adjoin in the column direction in two adjacent memory cells arranged in column and the spacing between the gate electrodes of select gate transistors which adjoin in the column direction in two adjacent memory cells arranged in column.

### CROSS-REFERENCE TO RELATED APPLICATIONS

This application is based upon and claims the benefit of priority from prior Japanese Patent Application No. 2005-330417, filed Nov. 15, 2005, the entire contents of which are incorporated herein by reference.

### BACKGROUND OF THE INVENTION

1. Field of the Invention

The present invention relates to a nonvolatile semiconductor storage device containing a nonvolatile memory and a method of manufacture thereof and more particularly to the memory cell array of a NOR-type flash memory having a two-transistor structure.

2. Description of the Related Art

A memory cell array in which memory cell units of two-transistor structure are arranged in rows and columns is known as the memory cell array of a NOR-type flash memory. Each of the memory cell units has a nonvolatile memory cell transistor of the double gate structure and a select gate transistor which controls the cell transistor. The memory cell units have first portions in which the cell transistors of two memory cell units which adjoin in the column direction share a drain region and second portions in which the select gate transistors of two memory cell unit which adjoin in the column direction share a source region. The first and second portions are arranged to alternate with each other. The active regions of the cell transistor and the select gate transistor in each memory cell are formed in one well region formed in the surface region of a semiconductor substrate. A trench isolation region is placed between every two adjacent rows of memory cell units.

The spacing between the gate electrodes of the cell and select gate transistors which adjoin in the column direction in each memory cell unit (row spacing) does not contribute to the device characteristics; therefore, it is desired that the gate spacing be reduced as far as possible. However, there is a limit on the reduction in gate spacing due to the limitations of lithographic techniques. It is therefore difficult to reduce the area of each memory cell unit and to reduce the size of the memory cell array as well.

Japanese Unexamined Patent Publication No. 2000-173979 (FIGS. 1 and 2) discloses a method to form finer patterns than the resolution of exposure apparatus. With this method, first, a polysilicon film and a silicon nitride film are formed in sequence over the surface of a silicon substrate. Next, a photoresist layer is formed and then exposure is made to transfer a pattern onto the photoresist layer at the limit resolution of exposure apparatus. After development, the silicon nitride film is patterned using the photoresist layer as a mask. Then, the photoresist layer is removed and then a silicon oxide film is formed over the entire surface. The silicon oxide film is then subjected to an anisotropic etching process and is consequently left only on the sidewall portions of the silicon nitride film. After that, the silicon nitride film is removed with the result that the sidewall portions consisting of the silicon oxide film are left. Further, a fresh silicon oxide film is formed and then subjected to an anisotropic etching process, thereby obtaining a pattern finer than the limit resolution of the exposure apparatus. BRIEF SUMMARY OF THE INVENTION

According to a first aspect of the present invention, there is provided a nonvolatile semiconductor storage device comprising: a NOR-type memory cell array in which a plurality of memory cell units is arranged in rows and columns on a semiconductor substrate, each of the memory cell units has a cell transistor with a control gate electrode and a select gate transistor with a gate electrode which are connected in series with each other, and the spacing between the gate electrodes of the cell and select gate transistors which adjoin in the column direction in each memory cell unit is determined in a self-aligned manner and shorter than the spacing between two memory cell units which adjoin in the column direction; and device isolation regions each of which is placed to provide isolation between adjacent rows of memory cell units.

According to a second aspect of the present invention, three is provided a method of manufacturing a nonvolatile semiconductor storage device comprising the steps of: depositing gate electrode materials over the semiconductor substrate with a gate insulating film interposed therebetween; forming a mask material processed to dimensions below the limitations of lithographic techniques used in processes over the top of the gate electrode materials; and anisotropically etching the gate electrode materials using the mask material to form the control gate electrode of the cell transistor and the gate electrode of the select gate electrode in a self-aligned manner.

### BRIEF DESCRIPTION OF THE SEVERAL VIEWS OF THE DRAWING

FIG. 1 shows the circuit arrangement of a NOR-type flash memory according to a first embodiment of the present invention;

FIG. 2 shows the layout of the memory cell array of the NOR-type flash memory shown in FIG. 1;

FIG. 3 is a sectional view taken along line III-III of FIG. 2;

FIG. 4 is a sectional view taken along line IV-IV of FIG. 2; and

FIGS. 5A through 5H are sectional views, in the order of steps of manufacture, of the NOR-type flash memory shown in FIGS. 1 through 4.

### DETAILED DESCRIPTION OF THE INVENTION

A preferred embodiment of the present invention will be described hereinafter with reference to the accompanying drawings. In the description, corresponding parts are denoted by like reference numerals throughout the drawings to thereby simplify the description.

### First Embodiment

In the first embodiment, a description is given of an example of the structure of the memory cell array of a NOR-type flash memory having the two-transistor structure.

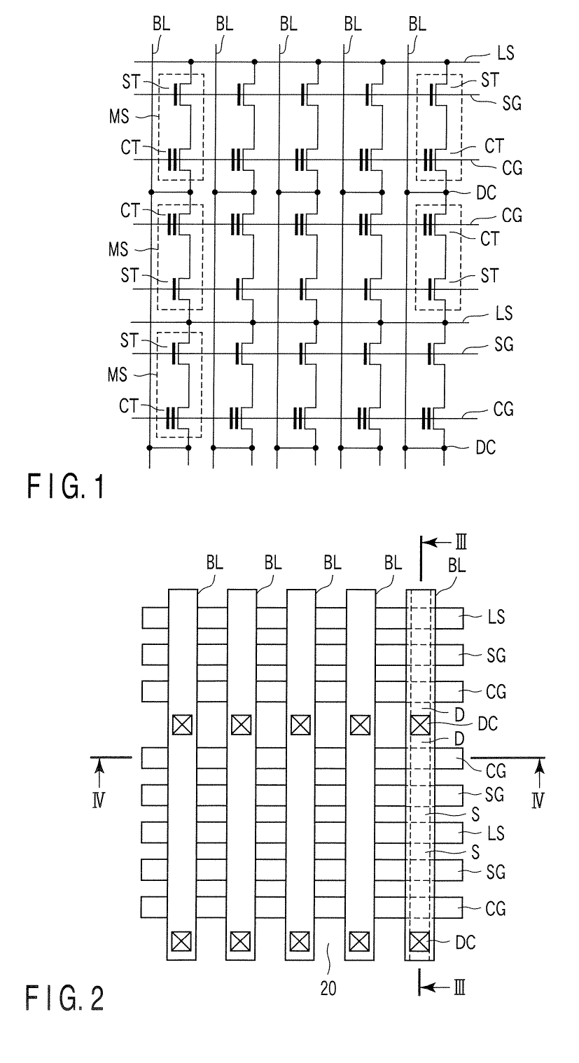

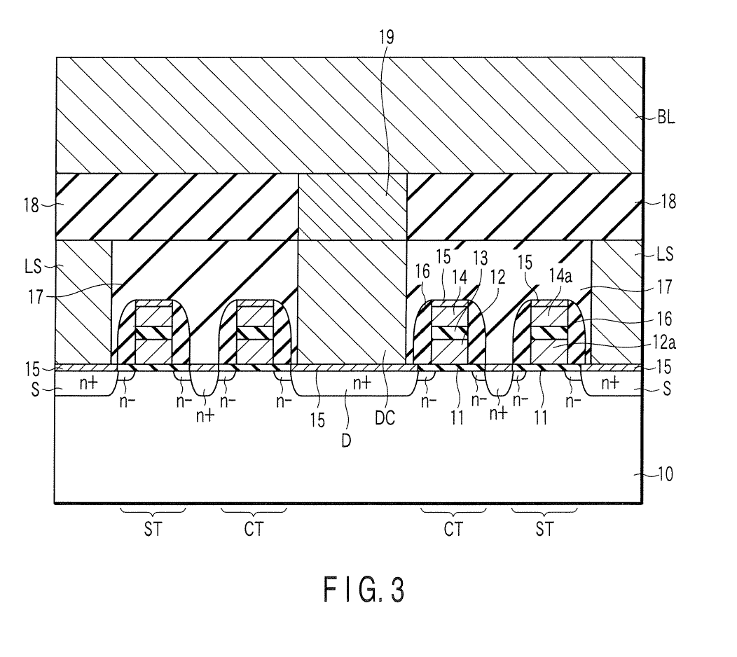

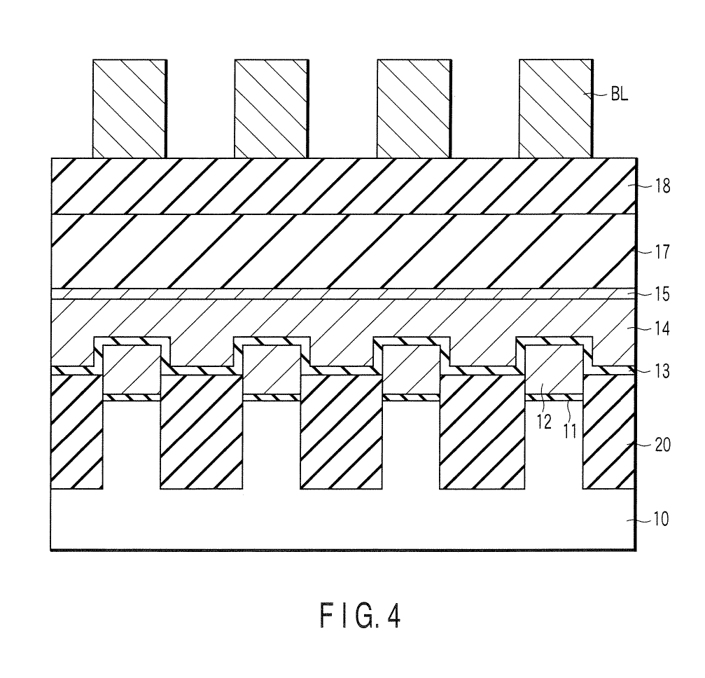

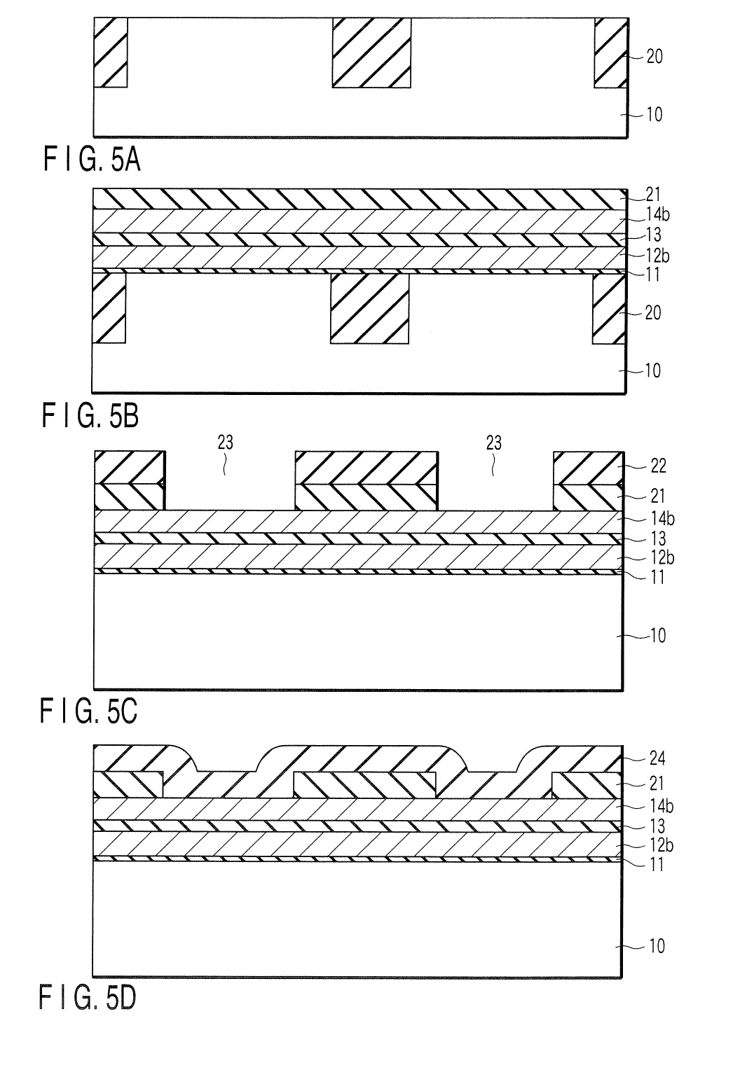

FIG. 1 shows the circuit arrangement of the memory cell array of the NOR-type flash memory of the first embodiment of the present invention. FIG. 2 shows the layout of the memory cell array of the NOR-type flash memory shown in FIG. 1. FIG. 3 is a sectional view taken along line III-III of FIG. 2 and FIG. 4 is a sectional view taken along line IV-IV of FIG. 2.

The NOR-type memory cell array shown in FIGS. 1 through 4 is formed in a well region formed in the surface region of a semiconductor substrate (a p-type silicon substrate in this example), for example, a p well 10 formed in the surface region of a deep n well.

As shown in FIG. 1, a plurality of memory cell units MS is arranged in rows and columns. Each of the memory cell units MS has a nonvolatile cell transistor CT and a select gate transistor ST which are connected in series with each other. The source region of the cell transistor CT is made common to the drain region of the select gate transistor ST.

As shown in FIG. 3, the cell transistor CT has an active region formed in the well region 10, i.e., source and drain diffusion regions and a channel region. A gate electrode of stacked structure is formed over the channel region with a gate insulating film (tunnel insulating film) 11 interposed therebetween. The gate electrode is comprised of three layers of a floating gate electrode 12, an intergate insulating film 13, and a control gate electrode 14. In this example, the floating gate electrode 12 is comprised of two layers of polysilicon. The integrate insulating film 13 is comprised of an oxide/nitride/oxide (ONO) composite film. The control gate electrode 14 is comprised of a polysilicon film formed on top with a metal silicide layer 15.

The select gate transistor ST has an active region formed in the same well region 10 as the cell transistor CT. As with the cell transistor CT, a gate electrode of three-layer structure is formed over the channel region with the gate insulating film 11 interposed therebetween. In this example, of a lower gate electrode 12a and an upper gate electrode 14a, the lower gate electrode 12a is used as the gate electrode of the select gate transistor ST. The gate electrode of three-layer structure of each of the cell transistor CT and the select gate transistor ST is formed with a silicon oxide film on the sidewall. When transistors of LDD structure are adopted as the transistors CT and ST as shown in FIG. 3, a gate sidewall insulating film 16 is formed on the sidewall of their respective gate electrode.

The memory cell units MS have first portions in which two cell transistors CT that adjoin in the column direction share a drain region D and second portions in which two select gate transistors ST share a source region S. The first and second portions are arranged to alternate with each other in the column direction. As shown in FIGS. 2 and 4, every two adjacent rows of memory cell units MS are isolated from each other by an isolation region 20 of shallow trench isolation (STI) structure.

The space between the control gate electrode of the cell transistor CT and the gate electrode of the select gate transistor ST in the memory cell unit MS is dead space which is not associated with the device characteristics. In this embodiment, the area occupied by a memory cell is reduced by narrowing the dead space. Specifically, the control gate electrode of the cell transistor CT and the gate electrode of the select gate transistor ST are formed in a self-aligned manner. Thereby, the spacing between the two gate electrodes is made smaller than the spacing between two memory cell units MS, i.e., the spacing between the gate electrodes of two cell transistors CT that adjoin in the column direction and the spacing between the gate electrodes of two select gate transistors ST that adjoin in the column direction.

As shown in FIGS. 1 and 2, a plurality of control gate lines CG is formed to extend in the row direction, each of which is connected in common to the control gate electrodes of cell transistors CT arranged in a corresponding row. Also, a plurality of select gate lines SG is formed to extend in the row direction, each of which is connected in common to the gate electrodes of select gate transistors ST arranged in a corresponding row.

As shown in FIG. 3, the gate electrodes of the cell transistor CT and select gate transistor ST are coated with a first interlayer insulating film 17. The space between the cell transistor and the select gate transistor in each memory cell unit which adjoin in the column direction is filled with the first interlayer insulating film 17 by way of example. Contact holes are formed in portions of the interlayer insulating film 17 each of which lies over a corresponding one of the drain regions D shared by the cell transistors CT. Each of the contact holes is filled with a drain contact layer DC which is in contact with the underlying drain region D. Furthermore, a second interlayer insulating film 18 is formed over the entire surface. Via holes are formed in portions of the interlayer insulating film 18 to expose the drain contact layers DC. The via holes are filled with a conducting material to form vias 19 each of which is in contact with a corresponding one of the drain contact layers DC. Moreover, a plurality of bit lines BEL, in the form of metal (e.g., tungsten), is formed on the second interlayer insulating film 18 to extend in the column direction. Each of the bit lines is brought into contact with the vias 19 arranged in a corresponding one of the columns.

Narrow contact holes are formed in portions of the first interlayer insulating film 17 each of which lies over a corresponding one of the source regions S shared by the adjacent select gate transistors ST. By filling these contact holes with a conducting material in the form of metal (e.g., tungsten), a plurality of local source lines LS is formed to extend in the row direction and lie across the device isolation regions 20. Each of the local source lines is brought into contact with the source regions S. Furthermore, a main source line, which consists of metal and is in contact with the bit lines BL, is formed intermittently within the arrangement of the bit lines BL to extend in the column direction.

Each of the select gate lines SG is formed by linking together the lower gate electrodes 12a of the select gate transistors ST arranged in the same row. In the select gate transistors ST placed in intermittent locations in the row direction, a portion of the intergate insulating film 13 between the upper and lower gate electrodes is removed. Through this removed portion, the upper select gate line SG is connected with an upper select gate interconnect line.

The drain regions D of the cell transistors CT, the source regions S of the select gate transistors ST, the control gate electrodes 14 of the cell transistors CT, and the upper gate electrodes 14a of the select gate transistors ST are each formed on top with a metal silicide layer 15.

As described above, the drain region D shared by two cell transistors CT which adjoin in the column direction is connected to a bit line BL of low resistivity through a drain contact DC. Also, the source region S shared by two select gate transistors ST which adjoin in the column direction is connected to a local source line LS arranged in parallel to the control gate lines (word lines) CG. The local source line LS is supplied with an arbitrary potential from the outside of the cell array through the main source line of low resistivity.

With the NOR-type flash memory configured as described above, data is written into a cell transistor CT when selected by the corresponding select gate transistor ST. Data writing is performed by injecting electrons into the floating gate electrode using channel hot electron injection. At the time of electron injection, the selected cell transistor CT is supplied at its well region with ground potential and at its source region S with ground potential through the select gate transistor ST. The control gate line CG and the bit line BL connected to the selected cell transistor CT are supplied from an external circuit with such desired potentials as allow the efficiency of generating hot electrons to be maximized.

Here, the spacing between the control gate electrode of the cell transistor CT and the gate electrode of the select gate transistor ST in each memory cell unit MS (i.e., the dead space which is not associated with the device characteristics) is processed to be below the limitations of lithographic techniques used in manufacturing this semiconductor device. Thereby, the area of each memory cell can be reduced. In other words, the two gate electrodes are formed in a self-aligned manner and the dead space is made shorter than the spacing between two memory cell units MS that adjoin in the column direction. Specifically, the dead space is made shorter than the spacing between the control gate electrodes of two cell transistors CT that adjoin in the column direction and the spacing between the gate electrodes of two select gate transistors ST that adjoin in the column direction.

The portion which is in contact with the common source region S of two select gate transistors ST in adjacent rows is connected to a linear interconnect line, i.e., a line-type local source interconnect line LS. In manufacturing steps, therefore, in filling the interlayer insulating film 17 between rows of the cell array after the gate electrodes of the cell transistor CT and the select gate transistor ST have been formed, the local source interconnect line LS can be buried with ease even if the spacing between rows is small. Thereby, the size of the cell array can be reduced.

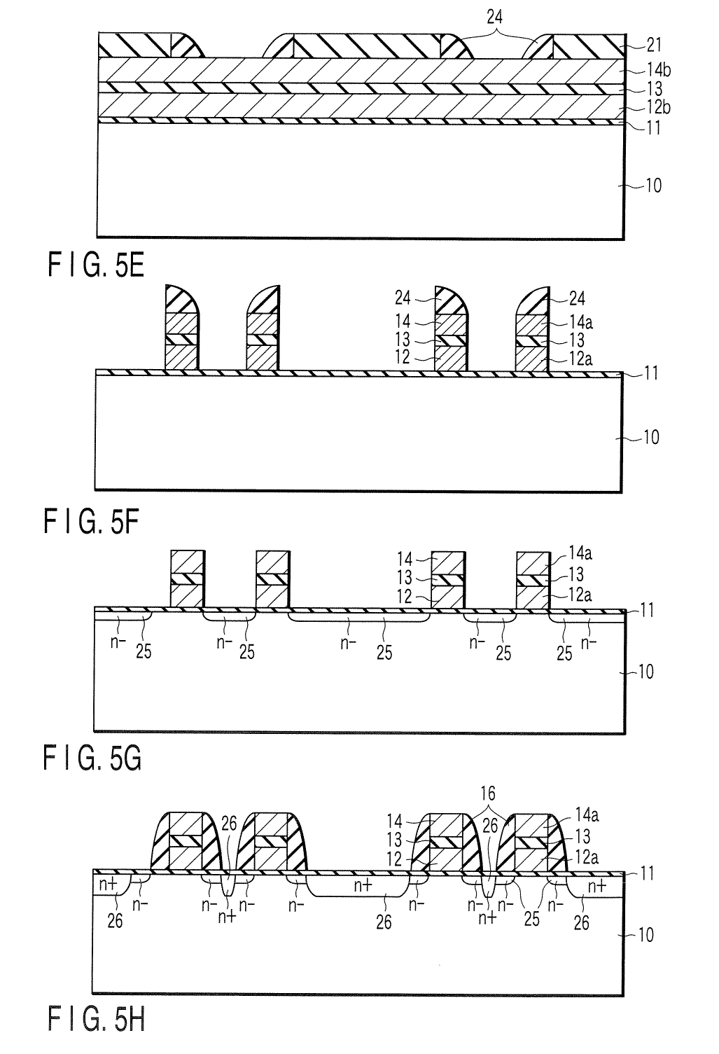

Next, the method of manufacturing the NOR-type flash memory according to the first embodiment will be described with reference to sectional views of FIGS. 5A through 5H.

First, as shown in FIG. 5A, a well region formed in the surface region of a semiconductor substrate (e.g., a p-type silicon substrate), that is, a p well 10 formed in the surface region in a deep n well in this example, is subjected to an anisotropic etching process using an etching mask to form a plurality of trenches. Then, the trenches are filled with an insulating film to form device isolation regions 20 of shallow trench structure.

Next, as shown in FIG. 5B, a gate insulating film 11 is formed over the entire surface after channel ion injection has been made. Then, a conducting film 12b of, say, polysilicon, an intergate insulating film 13, and a conducting film 14b of, say, polysilicon are sequentially deposited over the entire surface. The film 12b has a thickness of the order of 100 to 200 nm. The film 13 is a composite film of oxide/nitride/oxide (ONO) by way of example. An insulating film 21 is further deposited which is, for example, an oxide film serving as a masking material. The polysilicon films 12b and 14b are each doped with n-type impurities by way of example.

Next, as shown in FIG. 5C, a resist film 22 is coated onto the entire surface and then formed into the desired pattern. An anisotropic etching process is then carried out to form openings 23 in the insulating film 21.

Next, as shown in FIG. SD, an insulating film 24 consisting of, say, a nitride film is deposited over the entire surface. After that, the insulating film 24 is subjected to an anisotropic etching process. Thereby, as shown in FIG. 5E, the insulating film 24 is left on the sidewall of the patterned insulating film 21.

Next, as shown in FIG. 5F, the insulating film 21 is etched away and then the polysilicon film 14b, the intergate insulating film 13 and the polysilicon film 12b are etched into a given shape using the remaining insulating film 24 as a mask. Thereby, the stacked gate electrode of each of the cell transistors CT and the select gate transistors ST is formed.

Next, after a gate protective film has been formed by post-oxidation to surround the gate electrodes of stacked structure, lightly-doped, shallow diffused layers (n− regions) 25 are formed in the source and drain regions by means of ion implantation as shown in FIG. 5G. This is intended to form the cell transistors CT and the select gate transistors ST into the LDD structure. After that, the insulating film 24 is removed.

Subsequently, as shown in FIG. 5H, an insulating film is deposited over the entire surface and then subjected to an anisotropic etching process to form a gate sidewall insulating film 16 on the sidewall of each stacked gate electrode. At this point, the insulating film used in forming the gate sidewall insulating film 16 may be left between the row of cell transistors and the row of select gate transistors. After that, highly-doped, deep diffused layers (n+ regions) 26 are formed in the source and drain regions by means of ion implantation.

Next, as shown in FIG. 3, portions of the gate insulating film 11 which are present in areas where contact is to be made to the source and drain regions are etched away. Subsequently, in order to lower the contact resistance to the source and drain regions and the resistance of the gate interconnect lines, a thin film of a refractory metal, such as cobalt, nickel, etc., is vapor deposited over the entire surface by means of sputtering techniques. A heating process is then carried out to form a metal silicide layer 15 on the drain regions of the cell transistors CT, the source regions S of the select gate transistors ST, the control gate electrodes 14 of the cell transistors, and the upper gate electrodes 14a of the select gate transistors. The unreacted metal film is removed in the subsequent step.

Next, a silicon nitride film is deposited over the entire surface which is used as a stopper when contact holes are formed in a subsequent step. A first interlayer insulating film 17 of silicon oxide is deposited on the top of the silicon nitride film by means of low pressure chemical vapor deposition (LPCVD). After reflow of the first interlayer insulating film 17, it is polished and planarized by means of chemical mechanical polishing (CMP) to the extent that the gate electrodes are not exposed.

Next, using lithographic and drive processes, contact holes are formed in portions of the first interlayer insulating film 17 which are located over the common drain regions D of the cell transistors. Further, narrow contact holes are opened in the first interlayer insulating film 17 each of which is used for a local source line that interconnects the common source regions of the select gate transistors which are arranged in a row and adjoin with an STI region 20 interposed therebetween. The contact holes and the narrow contact holes for the local source lines may be formed at the same time.

Next, the contact holes and the narrow contact holes are filled with a conducting film in the form of a metal of, say, tungsten, thereby forming contact plugs DC for bit lines and the local source lines LS. In this example, the contact holes and the narrow contact holes are formed inside with a barrier metal and then filled with tungsten. The exposed portions are polished away by means of CMP. Thereby, the contact plugs DC and the local source lines LS are formed.

Next, a second interlayer insulating film 18 consisting of a TEOS-based oxide film is deposited over the entire surface. After reflow, that oxide film is planarized by CMP. Subsequently, using lithographic and drive processes, via holes for connection to the contact plugs DC and via holes for connection to the local source lines LS are opened by means of dry etching. Then, a barrier metal of, say, TiN is deposited and tungsten as a material of interconnect lines is deposited on the top of the barrier metal to fill the via holes. Subsequently, exposed areas of tungsten and barrier metal are removed by means of CMP. After the formation of vias 19 for connection to the bit lines, a metal film for interconnect lines is deposited and patterned, whereby the bit lines BL shown in FIG. 2 are formed. After that, upper levels of interconnections and a passivation layer are formed and openings are formed in positions corresponding to pad areas.

According to the manufacturing method described above, in forming the stacked gate electrodes of the cell transistor CT and the select gate transistor ST, anisotropic etching is carried out on gate electrode materials using a mask material formed thereon. Thereby, the spacing between the two gate electrodes is determined in a self-aligned manner. For this reason, the gate spacing can be reduced below the limit dimension realized by the lithographic techniques used in implementing the above method, thus allowing the area of each memory cell to be reduced.

### First Modification of the First Embodiment

In the first embodiment, the local source line LS is formed. In place of the local source line, a source contact layer may be formed which is in contact with the source regions S. Even such a modification will offer the same advantages as the first embodiment.

### Second Modification of the First Embodiment

In the first embodiment, each of the cell and select gate transistors has the LDD structure. However, this is not restrictive. If the cell and select gate transistors are not constructed into the LDD structure, after the stacked gate electrode of each of the cell and select gate transistors is formed and post-oxidation is performed, ion implantation may be carried out to form n+-type impurity regions as source and drain regions in the silicon substrate surface regions below the opposite sides of each gate electrode. Even such a modification will offer the same advantages as the first embodiment.

The semiconductor device of the present invention can be applied not only to a NOR-type flash memory but also to a flash memory which combines the features of NAND- and NOR-type flash memories. Furthermore, the invention may be carried out on a semiconductor integrated circuit device, called system on chip, in which various flash memories and logic circuits are integrated on one chip.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor storage device comprising:
a NOR-type memory cell array in which a plurality of memory cell units is arranged in rows and columns on a semiconductor substrate, each of the memory cell units has a cell transistor with a control gate electrode and a select gate transistor with a gate electrode which are connected in series with each other, and a spacing between the gate electrodes of the cell and select gate transistors which adjoin in the column direction in each memory cell unit is determined in a self-aligned manner and shorter than a spacing between two memory cell units which adjoin in the column direction; and
device isolation regions each of which is placed to provide isolation between adjacent rows of memory cell units.

2. The nonvolatile semiconductor storage device according to claim 1, wherein the cell transistor has a floating gate electrode which lies below the control gate electrode with a gate insulating film interposed therebetween.

3. The nonvolatile semiconductor storage device according to claim 2, wherein the gate electrode of the select gate transistor is comprised of a conducting film at the same level as the floating gate electrode of the cell transistor.

4. The nonvolatile semiconductor storage device according to claim 1, wherein the spacing between the gate electrodes of the cell and select gate transistors which adjoin in the column direction in each memory cell unit is set shorter than a spacing between the control gate electrodes of two cell transistors which adjoin in the column direction.

5. The nonvolatile semiconductor storage device according to claim 1, wherein the spacing between the gate electrodes of the cell and select gate transistors which adjoin in the column direction in each memory cell unit is set shorter than a spacing between the gate electrodes of two select gate transistors which adjoin in the column direction.

6. A nonvolatile semiconductor storage device comprising:
a memory cell array in which a plurality of memory cell units, each of which has a nonvolatile cell transistor with a control gate electrode of stacked gate structure and source and drain regions and a select gate transistor with a gate electrode of stacked gate structure and source and drain regions, are arranged in rows and columns on a semiconductor substrate, the source region of the cell transistor and the drain region of the select gate transistor are formed from a common region, every two cell transistors which adjoin in the column direction have a first portion in which their drain regions are formed from a common region, every two select gate transistors which adjoin in the column direction have a second portion in which their source regions are formed from a common region, the first and second portions arranged alternately, the spacing between the gate electrodes of the cell and select gate transistors in each memory cell unit is determined in a self-aligned manner and set shorter than the spacing between two memory cell units which adjoin in the column direction;
device isolation regions each of which is placed to provide isolation between adjacent rows of memory cell units;
a plurality of word lines each of which is formed in the row direction and connected in common to the control gate electrodes of the cell transistors arranged in a corresponding one of the rows;
a plurality of select gate lines each of which is formed in the row direction and connected in common to the gate electrodes of the select gate transistors arranged in a corresponding one of the rows;
a plurality of direct contact areas each of which is in contact with a corresponding first portion; and
a plurality of bit lines each of which is formed in the column direction and in contact with the direct contact areas arranged in a corresponding one of the columns.

7. The nonvolatile semiconductor storage device according to claim 6, wherein the cell transistor has a floating gate electrode which lies below the control gate electrode with a gate insulating film interposed therebetween.

8. The nonvolatile semiconductor storage device according to claim 7, wherein the gate electrode of the select gate transistor is comprised of a conducting film at the same level as the floating gate electrode of the cell transistor.

9. The nonvolatile semiconductor storage device according to claim 6, wherein the spacing between the gate electrodes of the cell and select gate transistors which adjoin in the column direction in each memory cell unit is set shorter than a spacing between the control gate electrodes of two cell transistors which adjoin in the column direction.

10. The nonvolatile semiconductor storage device according to claim 6, wherein the spacing between the gate electrodes of the cell and select gate transistors which adjoin in the column direction in each memory cell unit is set shorter than a spacing between the gate electrodes of two select gate transistors which adjoin in the column direction.

11. A method of manufacturing a nonvolatile semiconductor storage device in which a plurality of memory cell units each comprised of a cell transistor and a select gate transistor connected in series is arranged in rows and columns on a semiconductor substrate and adjacent rows of memory cell units are isolated by a device isolation region, comprising the steps of:
depositing gate electrode materials over the semiconductor substrate with a gate insulating film interposed therebetween;
forming a mask material processed to dimensions below the limitations of lithographic techniques used in processes over the top of the gate electrode materials; and
anisotropically etching the gate electrode materials using the mask material to form the control gate electrode of the cell transistor and the gate electrode of the select gate electrode in a self-aligned manner.

12. The method according to claim 11, wherein the mask material is formed by:
depositing a first insulating film over the gate electrode materials;
forming openings in the first insulating film to form the sidewall of the first insulating film;
depositing a second insulating film over the entire surface;
anisotropically etching the second insulating film, the second insulating film remains on the sidewall of the first insulating film; and
removing the first insulating film so that the remaining second insulating film forms the mask material.

13. The method according to claim 11, further comprising introducing impurities into the substrate using the gate electrodes of the cell and select gate transistors to form the source and drain regions of the cell and select gate transistors in the substrate, the source region of the cell transistor and the drain region of the select gate transistor are formed from a common region.

14. The method according to claim 13, further comprising forming a gate sidewall insulating film on the gate electrodes of the cell and select gate transistors before impurities are introduced into the substrate.

15. A method of manufacturing a nonvolatile semiconductor storage device comprising the steps of:
forming device isolation regions by filling trenches formed in selected portions of the surface region of a silicon substrate of a first conductivity type with a first insulating film;
depositing a gate insulating film, a first insulating film, a second insulating film, a second conducting film, and a third insulating film in sequence over the entire surface of the silicon substrate;
patterning the third insulating film to form a sidewall in the third insulating film;
deposing a fourth insulating film over the entire surface;
anisotropically etching the fourth insulating film to remains the fourth insulating film on the sidewall of the third insulating film;
removing the third insulating film;
etching the second conducting film, the second insulating film, and the first conducting film using the remaining fourth insulating film as a mask to form the control gate electrode of a cell transistor and the gate electrode of a select gate transistor, each of the gate electrodes having the stacked gate structure;
introducing impurities into the substrate using the gate electrodes of the cell and select gate transistors as a mask to form the drain and source regions of a second conductivity type of the cell and select gate transistors;
depositing an interlayer insulating film over the entire surface;
planarizing the interlayer insulating film to the extent that the gate electrodes of the cell and select gate transistors are not exposed;
forming a first opening in the interlayer insulating film; and
forming a drain contact layer in the first opening which is in contact with the drain region of the cell transistor.

16. The method according to claim 15, wherein the source region of the cell transistor and the drain region of the select gate transistor are formed as a common region.

17. The method according to claim 15, further comprising forming a second opening and forming a source line in the second opening which is in contact with the source region of the select gate transistor.

18. The method according to claim 15, further comprising, after the formation of the gate electrodes of the cell and select gate transistors, forming a gate sidewall insulating film on the gate electrodes of the cell and select gate transistors.
